(19) United States
(12) Patent Application Publication
(10) Pub. No.: US 2009/0020858 A1
(43) Pub. Date: Jan. 22, 2009

(54) TAPE CARRIER SUBSTRATE AND SEMICONDUCTOR DEVICE

(75) Inventors: Yukihiro Kozaka, Kyoto (JP); Yoshifumi Nakamura, Osaka (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 12/169,199

(22) Filed: Jul. 8, 2008

(30) Foreign Application Priority Data
Jul. 17, 2007 (JP) 2007-185133
Apr. 22, 2008 (JP) 2008-110806

(51) Int. Cl. H01L 23/495; B32B 3/10

(52) U.S. Cl. 257/667; 428/137; 257/E23.065

(57) ABSTRACT

The present invention provides a tape carrier substrate that can prevent a conductor wire on the tape carrier substrate from being broken at the boundary portion between the conductor wire and a slit formed in a folding portion of the tape carrier substrate. The slit is formed in the folding portion of the tape carrier substrate so that the width thereof located on an extensional portion side of the tape carrier substrate is larger than that located on a central portion side of the tape carrier substrate. Possible stress resulting from bending of the tape carrier substrate is thus distributed. This prevents the stress from concentrating at the boundary portion between the slit and the conductor wire.

### FIELD OF THE INVENTION

The present invention relates to a tape carrier substrate and a semiconductor device having semiconductor elements mounted on the tape carrier substrate.

### BACKGROUND OF THE INVENTION

A TAB (Tape Automated Bonding) technique is conventionally known which electrically connects conductor wires (leads) on a tape-like flexible tape carrier substrate to terminals on semiconductor elements via bumps (projecting electrodes). Semiconductor devices (TCPs: Tape Carrier Packages) manufactured by the TAB technique are used as drivers mounted on a panel of a flat panel display.

FIG. 22 shows a plan view of a conventional tape carrier substrate.

The tape carrier substrate 100 is designed for a 384-output plasma display panel (hereinafter referred to as a PDP). Two semiconductor elements can be mounted on the tape carrier substrate 100.

As shown in FIG. 22, the tape carrier substrate 100 comprises a pair of an input terminal group 102 and an output terminal group 103 provided on a first surface of a tape carrier base material 101. The paired input terminal group 102 and output terminal group 103 are arranged opposite each other in a width direction W of the tape carrier base material 101.

The tape carrier substrate 100 comprises two device holes 104 formed in the tape carrier base material 101. The two device holes 104 are arranged in a length direction L of the tape carrier base material 101. The shape of each of the device holes 104 is similar to the external shape of a rectangular semiconductor element mounted in the device hole 104. The area of the device hole 104 is slightly larger than the external area of the rectangular semiconductor element mounted in the device hole 104. The device hole 104 is formed so that a longitudinal direction of the device hole 104 is substantially parallel to the width direction W of the tape carrier base material 101.

The tape carrier substrate 100 comprises a plurality of conductor wires 105a and a plurality of conductor wires 105b provided on the first surface of the tape carrier base material 101 along the width direction W.

One end of each of the conductor wires 105a is connected to a terminal constituting the input terminal group 102. The other end of the conductor wire 105a is connected via a projecting electrode to a terminal of the semiconductor element mounted on the device hole 104. Similarly, one end of each of the conductor wires 105b is connected to a terminal constituting the output terminal group 103. The other end of the conductor wire 105b is connected via a projecting electrode to a terminal of the semiconductor element mounted on the device hole 104.

Specifically, each of the conductor wires 105a, 105b is made up of an installation wiring portion formed on the tape carrier base material 101 for connection to the input terminal group 102 or the output terminal group 103, and an inner lead supported by the underlying tape carrier base material 101 and projecting over the device hole 104. For example, copper is used to integrally form the conductor wire 105a and the terminal constituting the input terminal group 102. Similarly, copper is used to integrally form the conductor wire 105b and the terminal constituting the output terminal group 103.

A semiconductor device having the semiconductor elements mounted on the tape carrier substrate 100 is mounted on a panel of the PDP by folding the semiconductor device along the length direction L of the tape carrier base material 101. Thus, stress generated in a width direction of the panel (the length direction L of the tape carrier base material 101) is added to stress generated in the folding direction.

Thus, to relax the stress, the tape carrier substrate 100 comprises first slits 106 and 107 and a second slit 108 all formed in the tape carrier base material 101 as shown in FIG. 22.

The first slits 106 and 107 are formed along parallel folding portions A and B and shaped to be elongate in the length direction L of the tape carrier base material 101. The second slit 108 is formed such that a longitudinal direction of the second slit 108 crosses a longitudinal direction of the first slits 106 and 107. The second slit 108 is shaped to be elongate in the width direction W of the tape carrier base material 101. Specifically, each of the first slits 106 and 107 is divided into two segments at the center of the tape carrier substrate 100. The second slit 108 is formed such that the longitudinal direction of the second slit 108 passes through a gap between the segments into which each first slit is divided.

The tape carrier substrate 100 also comprises an insulating layer 109 provided on the first surface of the tape carrier base material 101 so as to cover the installation wiring portions of the conductor wires 105a and 105b. The insulating layer 109 is formed of an organic insulating material, for example, polyimide or epoxy.

Furthermore, although not shown in the drawings, the tape carrier substrate 100 comprises slit fillers provided on a second surface of the tape carrier base material 101. The slit fillers are formed of an organic insulating material, for example, polyimide or epoxy. The slit fillers cover parts of the conductor wires 105b exposed from the first slits 106 and 107 in the installation wiring portions.

Sprocket holes 110 are formed at opposite ends of the tape carrier base material 101 in the width direction W. Polyimide is often used as a material for the tape carrier base material 101. The width of the tape carrier base material 101 is generally 35, 48, or 70 mm.

FIG. 23 shows a sectional view of a semiconductor device (PDP driver) having the semiconductor elements mounted on the tape carrier substrate 100 as described above.

As shown in FIG. 23, the semiconductor device 111 comprises a rectangular semiconductor element 112 mounted on the device hole 104. A terminal (not shown) formed on a back surface of the semiconductor element 112 is connected to inner leads 115a and 115b of the conductor wires 105a and 105b via projecting electrodes 113. The semiconductor element 112 is mounted so that a longer side of the semiconductor element 112 is substantially parallel to the width direction W of the tape carrier base material 101.

A side (the back surface side of the semiconductor element 112) of the device hole 104 on which the projecting electrode 113 is located is molded with a molding resin 114. The back surface of the semiconductor element 112, the projecting electrodes 113, and the inner leads 115a and 115b are covered with the molding resin 114.

The conductor wire 105a is composed of the inner lead 115a projecting over the device hole 104 and an installation wiring portion 116a connected to the inner lead 115a and the input terminal group 102. Similarly, the conductor wire 105b is composed of the inner lead 115b projecting over the device hole 104 and an installation wiring portion 116b connected to the inner lead 115b and the output terminal group 103.

The insulating layer 109, covering the installation wiring portions 116a and 116b, is provided on the first surface of the tape carrier base material 101. Slit fillers 117 are provided on the second surface of the tape carrier base material 101 so as to cover parts of the installation wiring portion 116b which are exposed from the first slits 106 and 107.

Now, an example of a method of manufacturing the conventional semiconductor device 111 will be described.

First, a bonding tool is used to carry out thermo-compression bonding on the projecting electrodes 113 on the semiconductor element 112 and the inner leads 115a and 115b, formed on the device holes 104 in the tape carrier base material 101. A metal junction is thus formed.

Subsequently, the back surface of the semiconductor element 112, the projecting electrodes 113, and the inner leads 115a and 115b are potted with the molding resin 114 in order to electrically and physically protect the semiconductor element 112 and the inner leads 115a and 115b from deleterious environments such as an external force, humidity, and contaminants. The molding resin 114 is cured by heating after the potting.

After the semiconductor element is thus mounted on the tape carrier base material 101, the external shape of the tape carrier substrate 100 is punched out of the tape carrier base material 101.

Each of the projecting electrodes 113, located between the terminal of the semiconductor element 112 and one of the inner leads 115a and 115b, may be provided on the terminal of the semiconductor element 112 or on one of the inner leads 115a and 115b.

FIG. 24 shows the appearance of a PDP on which the above-described semiconductor device (PDP driver) 111 is mounted. FIG. 25 shows an enlarged diagram of a part of FIG. 24 shown by K. FIG. 26 shows a sectional view of the semiconductor device 111 mounted on the panel of the PDP.

With an increased driving voltage for recent PDPs, a panel and peripheral components such as a power source generate a significantly increased quantity of heat. Thus, as shown in FIGS. 24 to 26, the PDP has an aluminum chassis 120 stuck to a rear surface of a glass panel 118 via a heat radiating sheet 119 and having substantially the same size as that of the glass panel 118; the semiconductor device (driver) 111 and a power source and a signal control circuit board (neither of them is shown) are mounted on the aluminum chassis 120 for heat radiation.

That is, the semiconductor device 111 is housed in a small gap between the glass panel 118 and a housing by folding the semiconductor device 111 along the folding portions A and B toward a conductor wire forming surface (first surface) so that an output terminal group 103 side part of the semiconductor device 111 is mounted on a front surface of the glass panel 118, while an input terminal group 102-side part thereof is fixed to the aluminum chassis 120.

Specifically, the output terminal group 103 is located on the glass panel 118-side, and thermo-compressively bonded to the front surface of the glass panel 118 via an ACF (Anisotropic Conductive Film). The conductor wires on the tape carrier substrate are thus connected to the glass panel 118 via the output terminal group 103.

The input terminal group 102 on the semiconductor device 111 and the semiconductor elements (not shown) are arranged on the aluminum chassis 120-side. A metal plate 121 formed of, for example, aluminum is provided on the part of the semiconductor device 111 which is located on the aluminum chassis 120-side, in order to radiate heat from the semiconductor elements on the semiconductor device 111. The metal plate 121 contacts the aluminum chassis 120 to radiate heat from the semiconductor elements toward the aluminum chassis 120.

The metal plate 121 has recess portions (not shown) in which the respective semiconductor elements mounted on the tape carrier substrate are fitted. The metal plate 121 contacts the top surface of each of the semiconductor elements via grease (not shown) filled between the bottom of the corresponding recess portion and the top surface (located opposite a terminal forming surface (back surface) of the semiconductor element) of the semiconductor element and made up of silicon resin or conductive paste. A surface of the metal plate 121 located opposite the tape carrier substrate of the semiconductor device 111 is flat. The metal plate 121 contacts the tape carrier substrate via an adhesive such as a double-faced tape located between the flat surface and the tape carrier substrate.

Now, a method of mounting the semiconductor device 111 on the panel of the PDP will be described.

First, before the semiconductor device 111 is mounted on the panel of the PDP, the metal plate 121 is bonded to the semiconductor device 111 (see FIG. 27).

Subsequently, the output terminal group 103-side of the semiconductor device 111 is mounted on the glass panel 118.

The semiconductor device 111 is then folded at the folding portions A and B.

A screw 125 is threaded through a threaded hole 122 in the metal plate 121 and a threaded hole 124 preformed in a projecting portion 123 of the aluminum chassis 120.

The semiconductor device 111 is thus mounted on the PDP by being folded along the length direction L of the tape carrier substrate. Then, the PDP with the semiconductor device 111 mounted thereon is housed in the housing.

As described above, the slits are formed in the folding portions of the conventional tape carrier substrate. Thus, the tape carrier substrate can be easily folded at the folding portions and is resistant to the folding stress (see, for example, Japanese Patent Laid-Open No. 8-139126).

However, when the PDP is powered on or off, the temperature in the housing changes significantly. As a result, the following problems may occur.

That is, the change in temperature resulting from the power-on and -off thermally expands the glass panel and the aluminum chassis. Since the glass panel and the aluminum chassis are formed of different materials, a difference in thermal expansion occurs between the glass panel 118 and the aluminum chassis 120 as shown in FIGS. 28 and 29. For example, in a PDP with a screen size of the order of 65 inches, the difference in thermal expansion between the glass panel 118 and the aluminum chassis 120 is about 0.6 mm. Thus, heavy stress is applied, in the width direction of the panel (the length direction L of the tape carrier base material), to the tape carrier substrate of the semiconductor device (driver) 111 fixed so as to straddle the glass panel 118 and the aluminum chassis 120. The stress bends the tape carrier substrate. The stress resulting from the bending concentrates at the boundary portion between the conductor wire 105b and each of the first slits 106 and 107, corresponding to the folding portions of the tape carrier substrate. Consequently, as the PDP is repeatedly powered on and off to repeatedly change the temperature, the conductor wire 105b is likely to be broken at the boundary portion between each of the first slits 106 and 107 and the conductor wire 105b.

In particular, in flat panel display markets, the size of the screen has been rapidly increased. The sizes of the glass panel and the aluminum chassis have also been increased, further increasing the difference in thermal expansion. The drivers have thus been subjected to heavier stress.

### DISCLOSURE OF THE INVENTION

In view of the above-described problems, an object of the present invention is to provide a tape carrier substrate and a semiconductor device which are capable of preventing conductor wires on a tape carrier substrate from being broken.

To accomplish the object, the present invention forms a slit in a folding portion of the tape carrier substrate such that the width of the slit located on an extensional portion side of the tape carrier substrate is larger than that located on a central portion side of the tape carrier substrate with respect to the extensional portion side thereof, thus dispersing possible stress resulting from bending of the tape carrier substrate.

Alternatively, to accomplish the object, the present invention forms a notch in a longitudinal direction of the slit formed in the folding portion of the tape carrier substrate, in the extensional portion of the tape carrier substrate, thus dispersing the possible stress resulting from bending of the tape carrier substrate.

That is, a first tape carrier substrate according to the present invention includes a tape carrier base material, a first terminal portion and a second terminal portion both formed on the tape carrier base material, a device hole formed between the first and second terminal portions of the tape carrier base material, a first conductor wire formed on the tape carrier base material and having a first end connected to the first terminal portion and a second end projecting over the device hole, a second conductor wire formed on the tape carrier base material and having a first end connected to the second terminal portion and a second end projecting over the device hole, and a slit portion formed between the first and second terminal portions of the tape carrier base material. Among widths of the slit portion in a direction perpendicular to a length direction of the slit portion, a first width located on an extensional portion side of the tape carrier base material is larger than a second width located on a central portion side of the tape carrier base material with respect to the extensional portion side.

Furthermore, favorably, the slit portion is stepped or tapered such that the first width is larger than the second width. Alternatively, an end of the slit portion which is located on the extensional portion side of the tape carrier base material is shaped like a circle with a diameter larger than the second width, and the circle forms the first width.

A second tape carrier substrate according to the present invention includes a tape carrier base material, a first terminal portion and a second terminal portion both formed on the tape carrier base material, a device hole formed between the first and second terminal portions of the tape carrier base material, a first conductor wire formed on the tape carrier base material and having a first end connected to the first terminal portion and a second end projecting over the device hole, a second conductor wire formed on the tape carrier base material and having a first end connected to the second terminal portion and a second end projecting over the device hole, a slit portion formed between the first and second terminal portions of the tape carrier base material, and a notch portion formed in an extensional portion of the tape carrier base material so as to extend in a longitudinal direction of the slit portion.

Furthermore, favorably, the notch portion is tapered or curved such that a width thereof located opposite the slit portion is larger than that located closer to the slit portion.

Furthermore, as is the case with the above first tape carrier substrate, among widths of the slit portion in a direction perpendicular to a length direction of the slit portion, a first width located on an extensional portion side of the tape carrier base material may be larger than a second width located on a central portion side of the tape carrier base material with respect to the extensional portion side. Furthermore, in this case, as described above, favorably, the slit portion is stepped or tapered such that the first width is larger than the second width. Alternatively, an end of the slit portion which is located on the extensional portion side of the tape carrier base material is shaped like a circle with a diameter larger than the second width, and the circle forms the first width.

Furthermore, a semiconductor device according to the present invention includes the above-described first or second tape carrier substrate, and a semiconductor element mounted on the device hole in the tape carrier substrate and electrically connected to the first and second terminal portions via the first and second conductor wires.

The preferred embodiment can distribute possible stress resulting from bending of the tape carrier substrate of the driver fixed to a PDP so as to straddle a glass panel and an aluminum chassis. Thus, even if the PDP is repeatedly powered on and off to repeatedly significantly change the temperature in the housing of the PDP, the conductor wire is very unlikely to be broken at the boundary portion between the slit and the conductor wire. Therefore, the tape carrier substrate and semiconductor device according to the present invention are applicable to a semiconductor device mounted by being folded.

### BRIEF DESCRIPTION OF THE DRAWINGS

FIG. 1 is a plan view showing the configuration of a tape carrier substrate according to a first embodiment of the present invention;

FIG. 2 is an enlarged view showing a part of FIG. 1;

FIG. 3 is a plan view of a semiconductor device folded so as to shift obliquely from a regular folding position;

FIG. 4 is a plan view of the semiconductor device folded at the regular folding position;

FIG. 5 is a sectional view of a semiconductor device according to the first embodiment of the present invention;

FIG. 6 is a sectional view showing the semiconductor device according to the first embodiment of the present invention mounted on a panel of a PDP;

FIG. 7 is a plan view showing that a metal plate is bonded to the semiconductor device according to the first embodiment of the present invention;

FIG. 8 is a diagram showing the results of simulation analysis of the distribution of possible stress generated in a first slit with a constant slit width;

FIG. 9 is an enlarged diagram of a part of FIG. 8;

FIG. 10 is a diagram showing the results of simulation analysis of the distribution of possible stress generated in the first slit according to the first embodiment of the present invention;

FIG. 11 is an enlarged diagram of a part of FIG. 10;

FIG. 12 is a plan view showing the configuration of a tape carrier substrate according to a second embodiment of the present invention;

FIG. 13 is an enlarged diagram of a part of FIG. 12;

FIG. 14 is a plan view showing the configuration of a tape carrier substrate according to a third embodiment of the present invention;

FIG. 15 is an enlarged diagram of a part of FIG. 14;

FIG. 16 is a plan view showing the configuration of a tape carrier substrate according to a fourth embodiment of the present invention;

FIG. 17 is an enlarged diagram of a part of FIG. 16;

FIG. 18 is a plan view showing the configuration of a tape carrier substrate according to a fifth embodiment of the present invention;

FIG. 19 is an enlarged diagram of a part of FIG. 18;

FIG. 20 is a plan view showing the configuration of a tape carrier substrate according to a sixth embodiment of the present invention;

FIG. 21 is an enlarged diagram of a part of FIG. 20;

FIG. 22 is a plan view showing the configuration of a conventional tape carrier substrate;

FIG. 23 is a sectional view of a conventional semiconductor device;

FIG. 24 is a diagram of the appearance of a panel of a PDP on which the conventional semiconductor device is mounted;

FIG. 25 is an enlarged diagram of a part of FIG. 24;

FIG. 26 is a sectional view showing that the conventional semiconductor device is mounted on the panel of the PDP;

FIG. 27 is a plan view showing that a metal plate is bonded to the conventional semiconductor device;

FIG. 28 is a diagram showing the appearance of the PDP in which a difference in thermal expansion has occurred between a glass panel and an aluminum chassis; and

FIG. 29 is an enlarged diagram of a part of FIG. 28.

### DESCRIPTION OF THE EMBODIMENTS

### First Embodiment

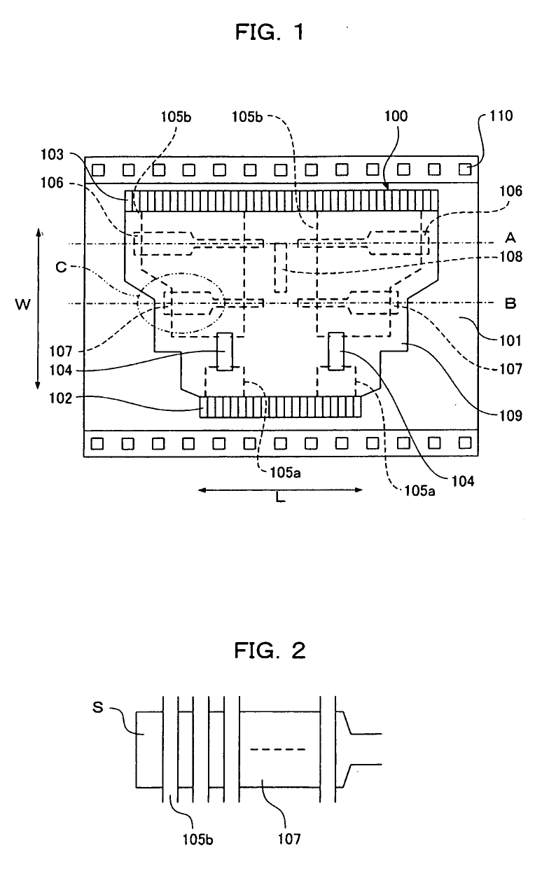

FIG. 1 is a plan view showing the configuration of a tape carrier substrate according to a first embodiment of the present invention. FIG. 2 is an enlarged perspective view of a part of FIG. 1 shown by C. A tape carrier substrate 100 is designed for a 384-output plasma display panel. Two semiconductor elements can be mounted on the tape carrier substrate 100.

As shown in FIG. 1, the tape carrier substrate 100 comprises an input terminal group 102 and an output terminal group 103 as a first terminal portion and a second terminal portion, provided on a first surface (conductor wire forming surface) of a tape carrier base material 101. Each of the input terminal group 102 and the output terminal group 103 is made up of a group of terminal (the first and second terminal groups) linearly arranged along a length direction L of the tape carrier base material 101. The terminal groups are arranged parallel to and opposite each other in a width direction W of the tape carrier base material 101.

The tape carrier substrate 100 comprises two device holes 104 formed between the input terminal group 102 and the output terminal group 103 on the tape carrier base material 101. The two device holes 104 are arranged in the length direction L of the tape carrier base material 101. The shape of each of the device holes 104 is similar to the external shape of a rectangular semiconductor element mounted in the device hole 104. The area of the device hole 104 is slightly larger than the external area of the rectangular semiconductor element mounted in the device hole 104. The device hole 104 is formed so that a longitudinal direction of the device hole 104 is substantially parallel to the width direction W of the tape carrier base material 101.

The tape carrier substrate 100 comprises a plurality of conductor wires 105a and a plurality of conductor wires 105b formed on the first surface of the tape carrier base material 101 along the width direction W.

One end of each of the conductor wires (first conductor wires) 105a is connected to a terminal constituting the input terminal group 102. The other end of the conductor wire 105a is connected via a projecting electrode to a terminal of the semiconductor element mounted on the device hole 104. Similarly, one end of each of the conductor wires (second conductor wires) 105b is connected to a terminal constituting the output terminal group 103. The other end of the conductor wire 105b is connected via a projecting electrode to a terminal of the semiconductor element mounted on the device hole 104.

Specifically, each of the conductor wires 105a, 105b is made up of an installation wiring portion formed on the tape carrier base material 101 for connection to the input terminal group 102 or the output terminal group 103, and an inner lead supported by the underlying tape carrier base material 101 and projecting over the device hole 104. For example, copper is used to integrally form the conductor wire 105a and the terminal constituting the input terminal group 102. Similarly, copper is used to integrally form the conductor wire 105b and the terminal constituting the output terminal group 103.

A semiconductor device having the semiconductor elements mounted on the tape carrier substrate 100 is mounted on a panel of a PDP by folding the semiconductor device along the length direction L of the tape carrier base material 101. Thus, stress generated in a width direction of the panel (the length direction L of the tape carrier base material 101) is added to stress generated in the folding direction.

Thus, to relax the stress, the tape carrier substrate 100 comprises first slits 106 and 107 and a second slit 108 all formed between the input terminal group 102 and the output terminal group 103 on the tape carrier base material 101.

The first slits 106 and 107 are formed along parallel folding portions A and B and shaped to be elongate in the length direction L of the tape carrier base material 101. The second slit 108 is formed such that a longitudinal direction of the second slit 108 crosses a longitudinal direction of the first slits 106 and 107. The second slit 108 is shaped to be elongate in the width direction W of the tape carrier base material 101. Specifically, each of the first slits 106 and 107 is divided into two segments at the center of the tape carrier substrate 100. The second slit 108 is formed such that the longitudinal direction of the second slit 108 passes through a gap between the segments into which each first slit is divided.

Thus, in the first embodiment, the tape carrier substrate 100 comprises a first slit portion made up of the two first slits 106 formed along the folding portion A, and a second slit portion made up of the two first slits 107 formed along the folding portion B.

The tape carrier substrate 100 also comprises an insulating layer 109 provided on the first surface of the tape carrier base material 101 so as to cover the installation wiring portions of the conductor wires 105a and 105b. The insulating layer 109 is formed of an organic insulating material, for example, polyimide or epoxy.

Furthermore, although not shown in the drawings, the tape carrier substrate 100 comprises slit fillers provided on a second surface (the surface located opposite the conductor wire forming surface) of the tape carrier base material 101. The slit fillers are formed of an organic insulating material, for example, polyimide or epoxy. The slit fillers cover parts of the conductor wires 105b exposed from the first slits 106 and 107 in the installation wiring portions.

Sprocket holes 110 are formed at opposite ends of the tape carrier base material 101 in the width direction W. Polyimide is often used as a material for the tape carrier base material 101. The width of the tape carrier base material 101 is generally 35, 48, or 70 mm.

The tape carrier substrate and semiconductor device according to the first embodiment are different from the conventional tape carrier substrate and semiconductor device in the shapes of the first slits 106 and 107 as shown in FIGS. 1 and 2. That is, the first slits 106 and 107 according to the first embodiment are different from the conventional first slits in that among widths of each of the first slits 106 and 107 which widths are perpendicular to the longitudinal direction (the length direction L of the tape carrier base material 101) of the first slit, a width (first width) located on an extensional portion side of the tape carrier substrate 100 is larger than that (second width) located on a central portion side of the tape carrier substrate 100 with respect to the extensional portion side. Specifically, each of the first slits 106 and 107 has a step shape in which the width located on the extensional portion side of the tape carrier substrate 100 is larger than the slit width (second width).

With the first slits 106 and 107 shaped as described above, even when a PDP driver constructed using the tape carrier substrate 100 is fixed so as to straddle the glass panel and aluminum chassis of the PDP, possible stress resulting from bending of the tape carrier substrate can be distributed over a wider surface S (see FIG. 2) of each of the first slits 106 and 107. Thus, the stress can be prevented from concentrating at the boundary portion between each of the first slits 106 and 107 and the conductor wire 105b.

Although the stress can be prevented from concentrating at the boundary portion between each of the first slits 106 and 107 and the conductor wire 105b by increasing the entire slit width of the first slits 106 and 107, the following problems may occur.

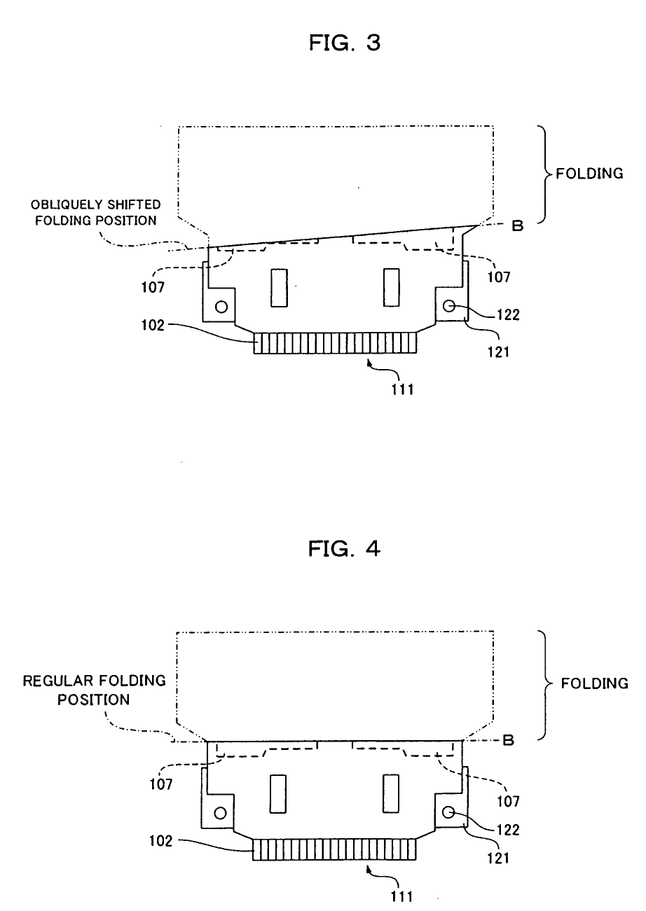

That is, the increased width of the first slits 106, 107 increases the difference between a regular folding position and the actual folding position. Then, as shown in FIG. 3, the actual folding position of the semiconductor device 111 is likely to shift obliquely from the regular folding position (see FIG. 4). If the semiconductor device 111 is mounted on the panel of the PDP with the folding position shifted from the regular position, stress generated in a width direction of the panel is added to stress generated in a folding direction. These stresses distort the tape carrier substrate, disadvantageously breaking the conductor wires or cracking molding resin or degrading the reliability of the connection between the PDP and the semiconductor device.

In contrast, in the first embodiment, each of the first slits 106 and 107 is shaped to have a larger width only on an extensional portion side of the tape carrier substrate 100, where the tape carrier substrate 100 is significantly bent by stress applied in the width direction of the panel. This enables a reduction in the error in the folding position, thus preventing the actual folding position from shifting obliquely from the regular folding position.

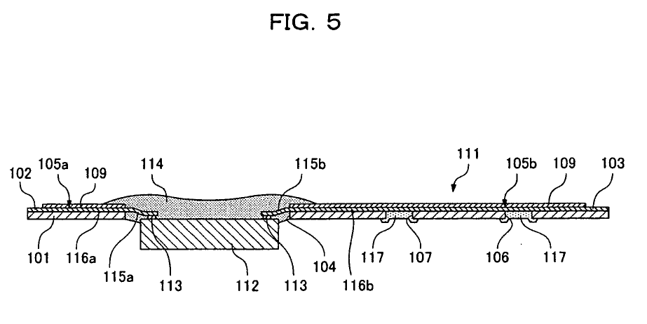

FIG. 5 is a sectional view of a semiconductor device (PDP driver) having the semiconductor elements on the tape carrier substrate 100 as described above.

As shown in FIG. 5, the semiconductor device 111 comprises a rectangular semiconductor element 112 mounted on the device hole 104. A terminal (not shown) formed on a back surface of the semiconductor element 112 is connected to inner leads 115a and 115b of the conductor wires 105a and 105b via projecting electrodes 113. The semiconductor element 112 is mounted such that a longer side thereof is substantially parallel to the width direction W of the tape carrier base material 101.

A side (the back surface side of the semiconductor element 112) of the device hole 104 on which the projecting electrode 113 is located is molded with a molding resin 114. The back surface of the semiconductor element 112, the projecting electrodes 113, and the inner leads 115a and 115b are covered with the molding resin 114.

The conductor wire 105a is composed of the inner lead 115a projecting over the device hole 104 and an installation wiring portion 116a connected to the inner lead 115a and the input terminal group 102. Similarly, the conductor wire 105b is composed of the inner lead 115b projecting over the device hole 104 and an installation wiring portion 116b connected to the inner lead 115b and the output terminal group 103.

The insulating layer 109, covering the installation wiring portions 116a and 116b, is provided on the first surface of the tape carrier base material 101. Slit fillers 117 are provided on the second surface of the tape carrier base material 101 so as to cover parts of the installation wiring portion 116b which are exposed from the first slits 106 and 107.

Now, an example of a method of manufacturing the semiconductor device 111 will be described.

First, a bonding tool is used to carry out thermo-compression bonding on the projecting electrodes 113 on the semiconductor element 112 and the inner leads 115a and 115b, formed on the device holes 104 in the tape carrier base material 101. A metal junction is thus formed.

Subsequently, the back surface of the semiconductor element 112, the projecting electrodes 113, and the inner leads 115a and 115b are potted with the molding resin 114 in order to electrically and physically protect the semiconductor element 112 and the inner leads 115a and 115b from deleterious environments such as an external force, humidity, and contaminants. The molding resin 114 is cured by heating after the potting.

After the semiconductor element is thus mounted on the tape carrier base material 101, the external shape of the tape carrier substrate 100 is punched out of the tape carrier base material 101.

Each of the projecting electrodes 113, located between the terminal of the semiconductor element 112 and one of the inner leads 115a and 115b, may be provided on the terminal of the semiconductor element 112 or on one of the inner leads 115a and 115b.

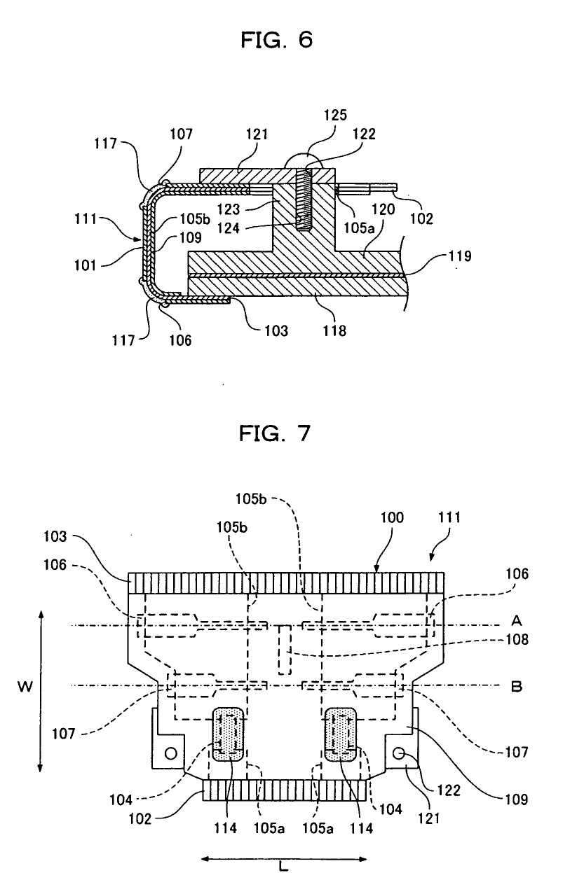

FIG. 6 shows a sectional view showing that the above-described semiconductor device (PDP driver) 111 is mounted on a panel of a PDP.

As shown in FIG. 6, the PDP has an aluminum chassis 120 stuck to a rear surface of a glass panel 118 via a heat radiating sheet 119 and having substantially the same size as that of the glass panel 118; the semiconductor device (driver) 111 and a power source and a signal control circuit board (neither of them is shown) are mounted on the aluminum chassis 120 for heat radiation.

That is, the semiconductor device 111 is housed in a small gap between the glass panel 118 and a housing by folding the semiconductor device 111 along the folding portions A and B toward a conductor wire forming surface (first surface) so that an output terminal group 103-side part of the semiconductor device 111 is mounted on a front surface of the glass panel 118, while an input terminal group 102-side part thereof is fixed to the aluminum chassis 120.

Specifically, the output terminal group 103 is located on the glass panel 118-side, and thermo-compressively bonded to the front surface of the glass panel 118 via an ACF (Anisotropic Conductive Film). The conductor wires 105b on the tape carrier substrate are thus connected to the glass panel 118 via the output terminal group 103.

The input terminal group 102 on the semiconductor device 111 and the semiconductor elements (not shown) are arranged on the aluminum chassis 120-side. A metal plate 121 formed of, for example, aluminum is provided on the part of the semiconductor device 111 which is located on the aluminum chassis 120-side, in order to radiate heat from the semiconductor elements on the semiconductor device 111. The metal plate 121 contacts the aluminum chassis 120 to radiate heat from the semiconductor elements toward the aluminum chassis 120.

The metal plate 121 has recess portions (not shown) in which the respective semiconductor elements mounted on the tape carrier substrate are fitted. The metal plate 121 contacts the top surface of each of the semiconductor elements via grease (not shown) filled between the bottom of the corresponding recess portion and the top surface (located opposite a terminal forming surface (back surface) of the semiconductor element) of the semiconductor element and made up of silicon resin or conductive paste. A surface of the metal plate 121 located opposite the tape carrier substrate of the semiconductor device 111 is flat. The metal plate 121 contacts the tape carrier substrate via an adhesive such as a double-faced adhesive tape located between the flat surface and the tape carrier substrate.

Now, a method of mounting the semiconductor device 111 on the panel of the PDP will be described.

First, before the semiconductor device 111 is mounted on the panel of the PDP, the metal plate 121 is bonded to the semiconductor device 111 (see FIG. 7).

Subsequently, the output terminal group 103-side of the semiconductor device 111 is mounted on the glass panel 118.

The semiconductor device 111 is then folded at the folding portions A and B.

A screw 125 is threaded through a threaded hole 122 in the metal plate 121 and a threaded hole 124 preformed in a projecting portion 123 of the aluminum chassis 120.

Now, description will be given of stress generated in the first slits, the folding portions of the tape carrier substrate, when the semiconductor device (driver) mounted on the panel of the PDP is stressed in the width direction of the panel to bend the tape carrier substrate.

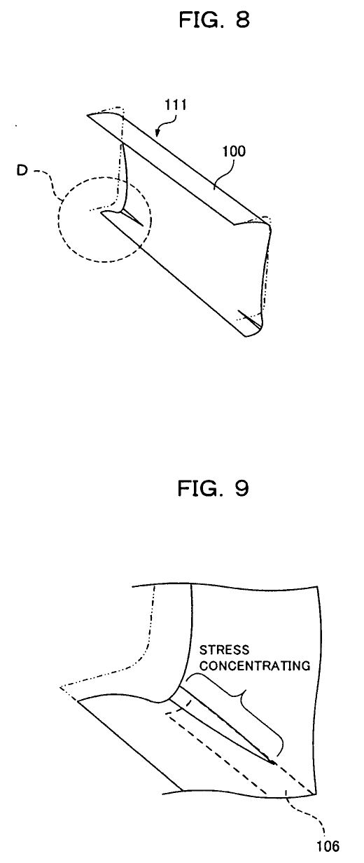

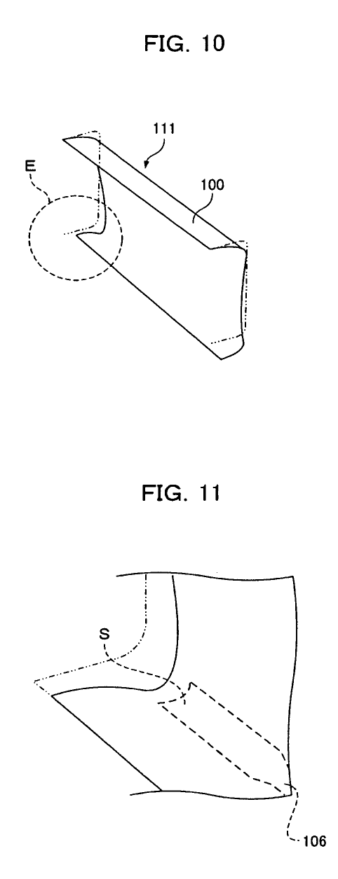

FIG. 8 is a diagram showing the results of simulation analysis of the distribution of possible stress generated in the conventional first slits 106 and 107 with the constant slit widths. FIG. 9 is an enlarged diagram of a part of FIG. 8 shown by D. FIG. 10 is a diagram showing the results of simulation analysis of the distribution of possible stress generated in the first slits 106 and 107 according to the first embodiment. FIG. 11 is an enlarged diagram of a part of FIG. 10 shown by E.

As shown in FIGS. 8 and 9, the constant slit width causes stress concentration at an edge portion of each of the first slits 106 and 107. In contrast, as shown in FIGS. 10 and 11, when each of the first slits 106 and 107 is wider on the extensional portion side of the tape carrier substrate, the stress on the edge portion of the first slit 106, 107 decreases by about 35%. This indicates that the stress is distributed.

As described above, for each of the first slits formed in the folding portion of the tape carrier substrate, the width thereof (first width) located on the extensional portion side of the tape carrier substrate is set larger than that (second width) located on the central portion side of the tape carrier substrate with respect to the extensional portion side. Then, possible stress resulting from bending of the tape carrier substrate can be distributed over the wider surface S of the first slit. This can prevent possible stress from concentrating at the boundary portion between the first slit and the conductor wire. The conductor wire can thus be prevented from being broken, thus improving the reliability of the connection between the PDP and the semiconductor device (driver).

In the first embodiment, the single second slit is formed in the center of the tape carrier substrate 100. However, of course, a plurality of the second slits may be formed. Furthermore, the two first slits 106 are formed along the folding portion A of the tape carrier substrate 100, and the two first slits 107 are formed along the folding portion B of the tape carrier substrate 100. However, of course, either a single first slit or at least three first slits may be formed.

### Second Embodiment

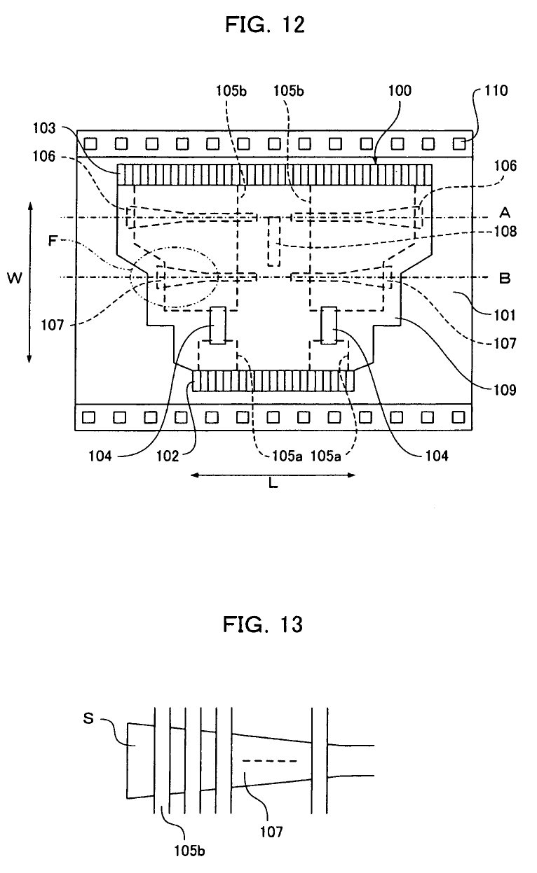

FIG. 12 is a plan view showing the configuration of a tape carrier substrate according to a second embodiment of the present invention. FIG. 13 is an enlarged perspective view of a part of FIG. 12 shown by F. However, the same members in the second embodiment as those described above in the first embodiment are denoted by the same reference numerals. Description thereof is omitted.

The tape carrier substrate and a semiconductor device according to the second embodiment are different from those according to the first embodiment in that first slits 106 and 107 are tapered such that the width thereof (first width) located on an extensional portion side of a tape carrier substrate 100 is larger than that (second width) located on a central portion side of the tape carrier substrate 100 with respect to the extensional portion side.

The first slits 106 and 107 shaped as described above can have minimum required opening areas. The reduced opening areas of the first slits 106 and 107 facilitate control of the thickness of an insulating layer 109. This improves the patterning accuracy with which the insulating layer 109 is printed. Thus, the manufacturing yield of the tape carrier substrate can be improved.

### Third Embodiment

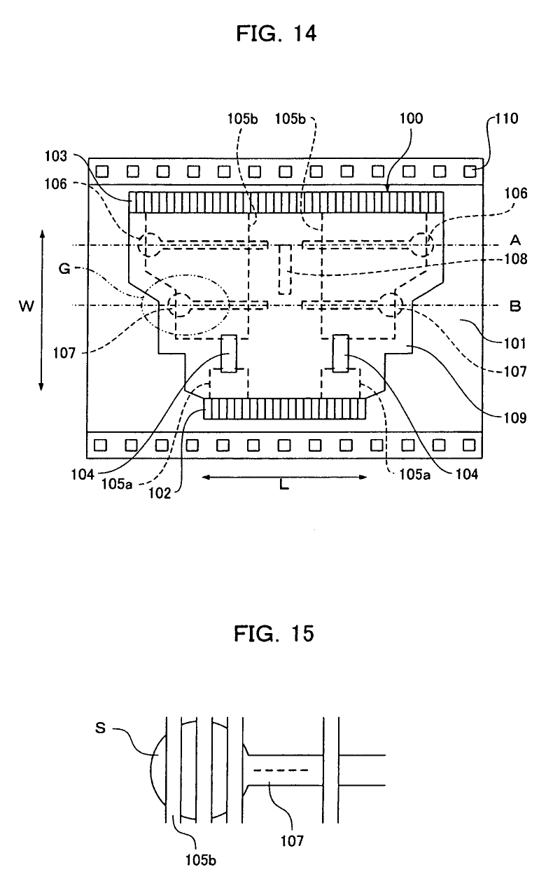

FIG. 14 is a plan view showing the configuration of a tape carrier substrate according to a third embodiment of the present invention. FIG. 15 is an enlarged perspective view of a part of FIG. 14 shown by G. However, the same members in the third embodiment as those described above in the first embodiment are denoted by the same reference numerals. Description thereof is omitted.

The tape carrier substrate and a semiconductor device according to the third embodiment are different from those according to the first embodiment in that ends, located on an extensional portion side of a tape carrier substrate 100, of first slits 106 and 107 are shaped like circles having diameters larger than the slit width thereof (second width).

The first slits 106 and 107 shaped as described above can have further reduced opening areas. This further facilitates control of the thickness of an insulating layer 109. This in turn further improves the patterning accuracy with which the insulating layer 109 is printed. Thus, the manufacturing yield of the tape carrier substrate can be improved.

### Fourth Embodiment

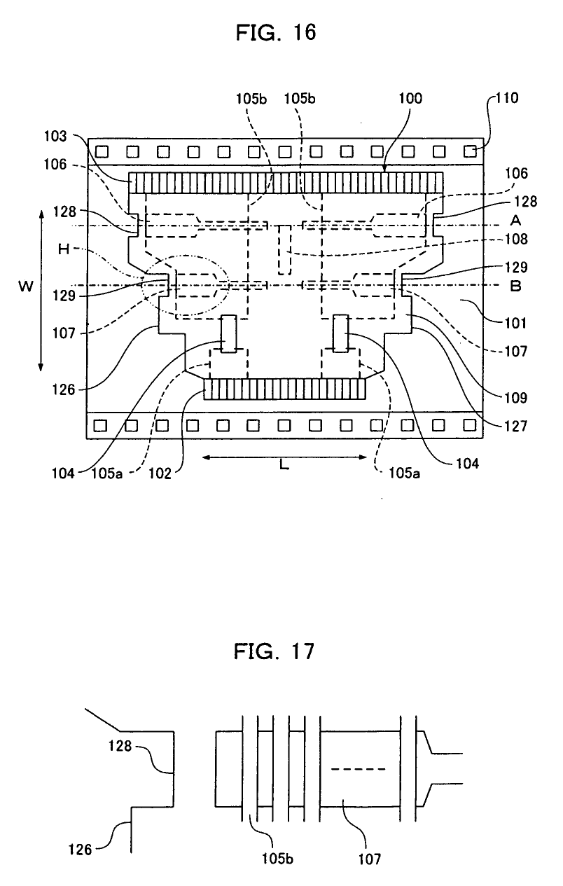

FIG. 16 is a plan view showing the configuration of a tape carrier substrate according to a fourth embodiment of the present invention. FIG. 17 is an enlarged perspective view of a part of FIG. 16 shown by H. However, the same members in the fourth embodiment as those described above in the first embodiment are denoted by the reference numerals. Description thereof is omitted.

The tape carrier substrate and a semiconductor device according to the fourth embodiment are different from those according to the first embodiment in that a notch portion 128 is formed at each of opposite ends (extensional portions) 126 and 127 of a tape carrier substrate 100 so as to extend in a longitudinal direction of corresponding one of first slits 106 and 107 toward the end of the first slit located on an extensional portion side of the tape carrier substrate 100.

The thus formed notch portion 128 also allows possible stress concentrating at the boundary portion between each of the first slits 106 and 107 and a conductor wire 105b to be distributed to the notch portion 128. This enables prevention of the possible stress concentration at the boundary portion between each of the first slits 106 and 107 and the conductor wire 105b. As a result, the conductor wires can be prevented from being broken and the reliability of the connection between a PDP and the semiconductor device (driver) can be improved.

### Fifth Embodiment

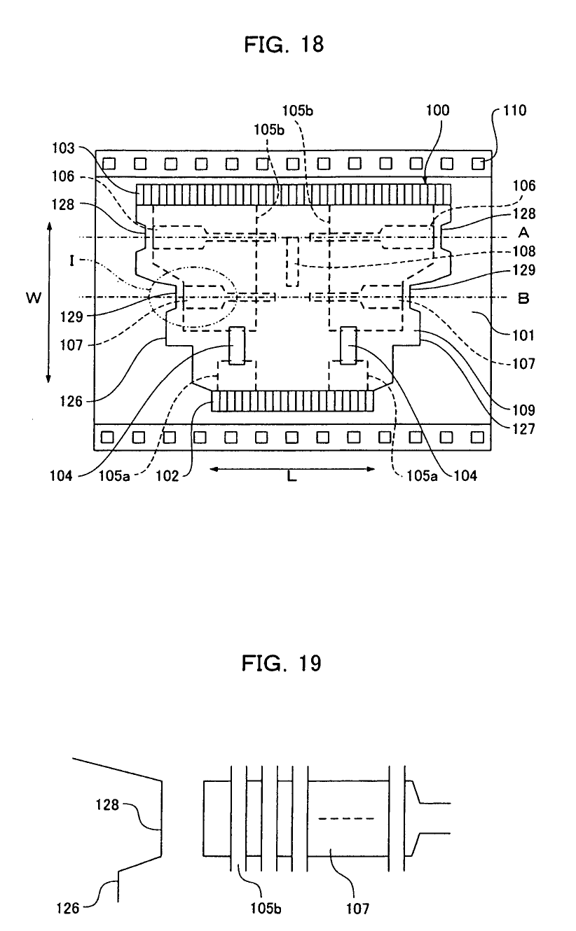

FIG. 18 is a plan view showing the configuration of a tape carrier substrate according to a fifth embodiment of the present invention. FIG. 19 is an enlarged perspective view of a part of FIG. 18 shown by I. However, the same members in the fifth embodiment as those described above in the fourth embodiment are denoted by the same reference numerals. Description thereof is omitted.

The tape carrier substrate and a semiconductor device according to the fifth embodiment are different from those according to the fourth embodiment in that a notch portion 128 is tapered such that the width thereof located opposite corresponding one of first slits 106 and 107 is larger than that located closer to the first slits.

The thus shaped notch portion 128 has an obtuse root and thus allows more stress to be distributed than a notch portion having a sharp root. Therefore, the fifth embodiment is effective in preventing, for example, disadvantageous cracking of the tape carrier substrate when the notch portion has a sharp root.

### Sixth Embodiment

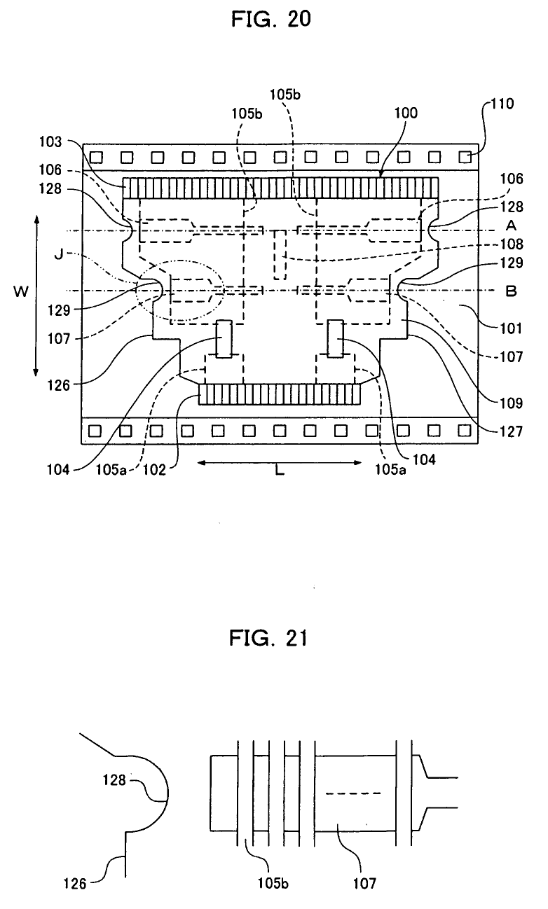

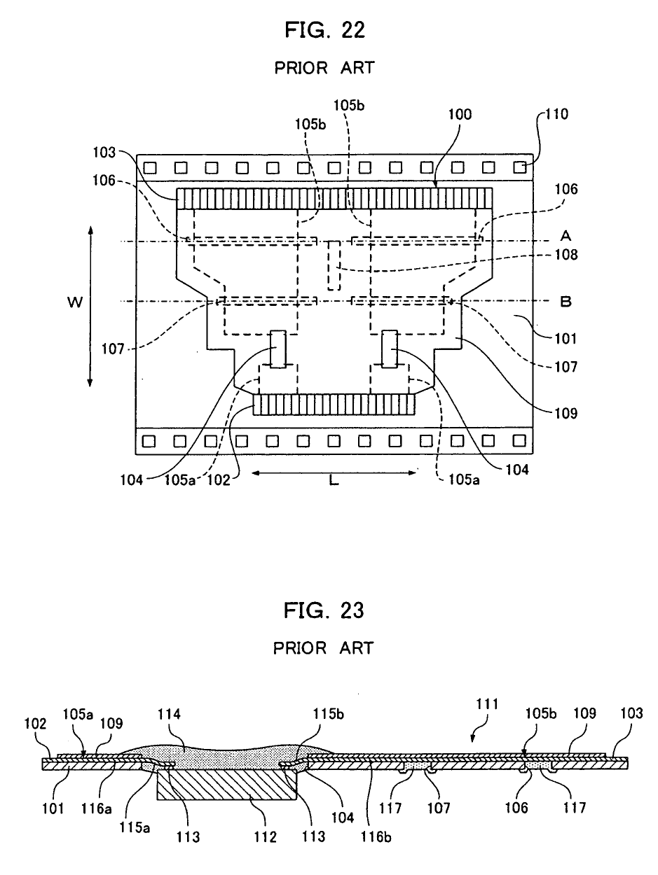

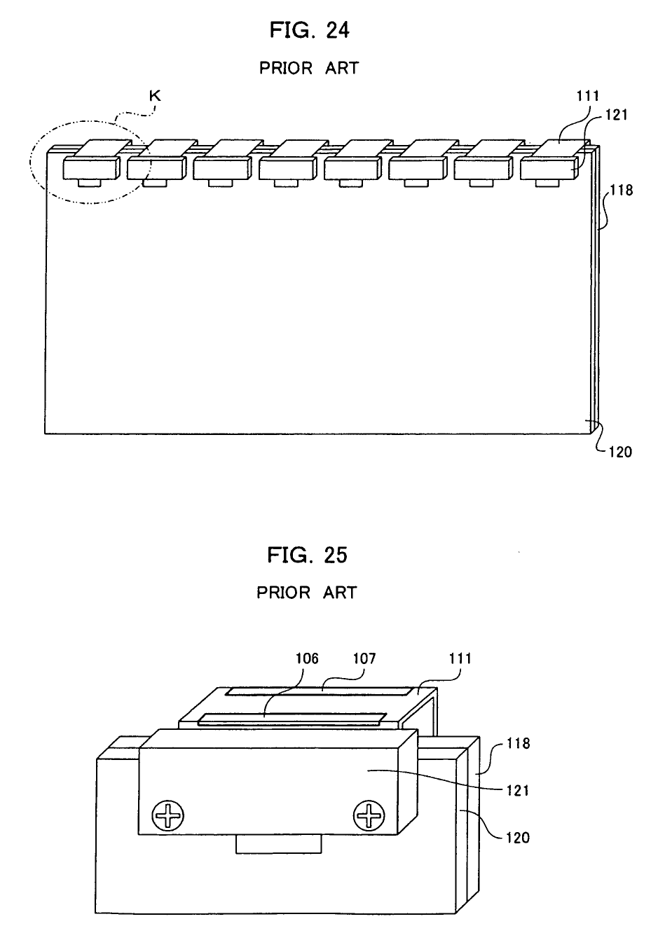

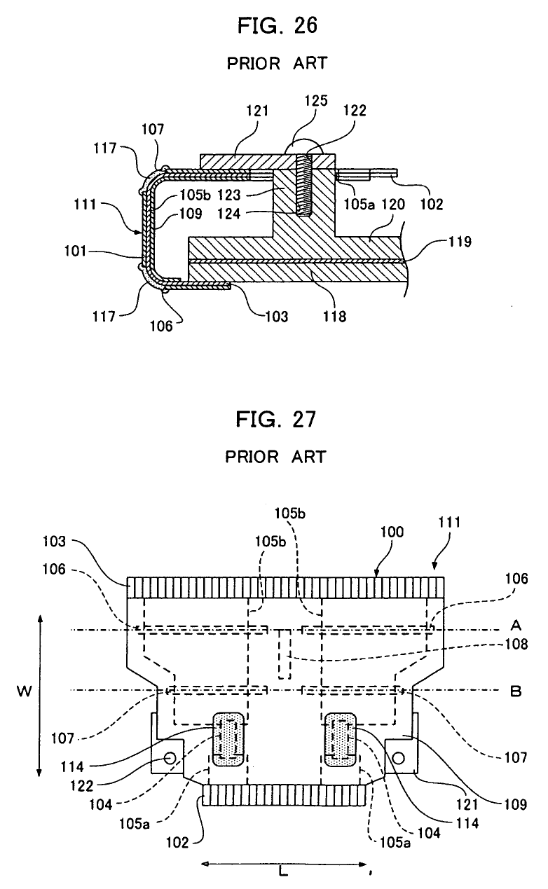

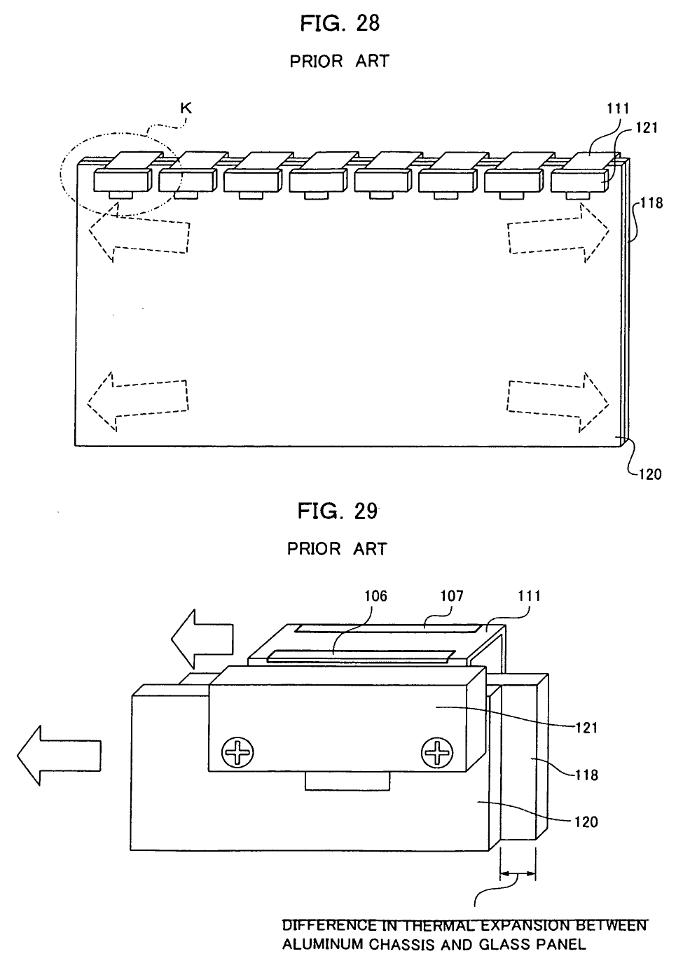

FIG. 20 is a plan view showing the configuration of a tape carrier substrate according to a sixth embodiment of the present invention. FIG. 21 is an enlarged perspective view of a part of FIG. 20 shown by J. However, the same members in the sixth embodiment as those described above in the fourth embodiment are denoted by the same reference numerals. Description thereof is omitted.

The tape carrier substrate and a semiconductor device according to the sixth embodiment are different from those according to the fourth embodiment in that a notch portion 128 is curved (in this case, shaped substantially like a semicircle) such that the width thereof located opposite corresponding one of first slits 106 and 107 is larger than that located closer to the first slits.

The thus shaped notch portion 128 allows more stress to be distributed than a notch portion formed of straight lines. This makes the tape carrier substrate more unlikely to be cracked.

The tape carrier substrates according to the fourth to sixth embodiments are configured to be the tape carrier substrate of the first embodiment provided with notch portions. However, of course, similar effects can be exerted by providing the tape carrier substrate according to one of the second and third embodiments with the above-described notch portions.

Alternatively, by forming the above-described notch portions in the conventional tape carrier substrate, in which the slits in the folding portions have uniform slit widths, possible stress concentrating at the boundary portion between the slit in the folding portions and the corresponding conductor wire can be distributed.

Therefore, the conductor wires can be prevented from being broken by forming the first slits, described in the first to third embodiments, forming the notch portions, described in the fourth to sixth embodiments, or combining the first slits, described in the first to third embodiments, with the notch portions, described in the fourth to sixth embodiments, depending on the screen size of the PDP, how the semiconductor device (driver) is mounted on the panel of the PDP, the size of the tape carrier substrate, and the like.

What is claimed is:

1. A tape carrier substrate comprising:
a tape carrier base material;
a first terminal portion and a second terminal portion both formed on the tape carrier base material;
a device hole formed between the first and second terminal portions of the tape carrier base material;
a first conductor wire formed on the tape carrier base material and having a first end connected to the first terminal portion and a second end projecting over the device hole;
a second conductor wire formed on the tape carrier base material and having a first end connected to the second terminal portion and a second end projecting over the device hole; and
a slit portion formed between the first and second terminal portions of the tape carrier base material, wherein among widths of the slit portion in a direction perpendicular to a length direction of the slit portion, a first width located on an extensional portion side of the tape carrier base material is larger than a second width located on a central portion side of the tape carrier base material with respect to the extensional portion side.

2. The tape carrier substrate according to claim 1, wherein the slit portion is stepped such that the first width is larger than the second width.

3. The tape carrier substrate according to claim 1, wherein the slit portion is tapered such that the first width is larger than the second width.

4. The tape carrier substrate according to claim 1, wherein an end of the slit portion which is located on the extensional portion side of the tape carrier base material is shaped like a circle with a diameter larger than the second width, and the circle forms the first width.

5. A tape carrier substrate comprising:
a tape carrier base material;
a first terminal portion and a second terminal portion both formed on the tape carrier base material;
a device hole formed between the first and second terminal portions of the tape carrier base material;
a first conductor wire formed on the tape carrier base material and having a first end connected to the first terminal portion and a second end projecting over the device hole;
a second conductor wire formed on the tape carrier base material and having a first end connected to the second terminal portion and a second end projecting over the device hole;
a slit portion formed between the first and second terminal portions of the tape carrier base material; and
a notch portion formed in an extensional portion of the tape carrier base material so as to extend in a longitudinal direction of the slit portion.

6. The tape carrier substrate according to claim 5, wherein the notch portion is tapered such that a width thereof located opposite the slit portion is larger than that located closer to the slit portion.

7. The tape carrier substrate according to claim 5, wherein the notch portion is curved such that a width thereof located opposite the slit portion is larger than that located closer to the slit portion.

8. The tape carrier substrate according to claim 5, wherein among widths of the slit portion in a direction perpendicular to the length direction of the slit portion, a first width located on an extensional portion side of the tape carrier base material is larger than a second width located on a central portion side of the tape carrier base material with respect to the extensional portion side.

9. The tape carrier substrate according to claim 8, wherein the slit portion is stepped such that the first width is larger than the second width.

10. The tape carrier substrate according to claim 8, wherein the slit portion is tapered such that the first width is larger than the second width.

11. The tape carrier substrate according to claim 8, wherein an end of the slit portion which is located on the extensional portion side of the tape carrier base material is shaped like a circle with a diameter larger than the second width, and the circle forms the first width.

12. A semiconductor device comprising the tape carrier substrate according to claim 1, and a semiconductor element mounted on a device hole in the tape carrier substrate and electrically connected to first and second terminal portions of the tape carrier substrate via first and second conductor wires of the tape carrier substrate.

13. A semiconductor device comprising the tape carrier substrate according to claim 5, and a semiconductor element mounted on a device hole in the tape carrier substrate and electrically connected to first and second terminal portions of the tape carrier substrate via first and second conductor wires of the tape carrier substrate.
